(19) United States
(12) Patent Application Publication
(10) Pub. No.: US 2008/0102207 A1
(43) Pub. Date: May 1, 2008

(54) Gas delivering system for in situ thermal treatment and thin film deposition and use of the same

(75) Inventors: Yu-Min Tsai, Dali City (TW); Hsiao-Che Wu, Zhongli City (TW); Wen-Li Tsai, Kaohsiung County (TW)

Correspondence Address: NIXON PEABODY LLP - PATENT GROUP, 1100 CLINTON SQUARE, ROCHESTER, NY, 14604, US

(73) Assignee: Promos Technologies Inc., Hsinchu (TW)

(21) Appl. No.: 11/715,619

(22) Filed: Mar. 8, 2007

(30) Foreign Application Priority Data
Oct. 25, 2006 (TW) 095139317

(51) Int. Cl. C23C 16/00; F16K 21/00

(52) U.S. Cl. 427/255.28; 118/715; 137/801

(57) ABSTRACT

A gas delivering system for an in situ thermal treatment, a thin film deposition and a use of the same are provided. The gas delivering system integrates a thermal treatment system therein so that a thin film deposition and a by rapid thermal annealing can be performed alternatively on a wafer in a reaction chamber. Accordingly, the density of the thin film can be improved and the thermal budget of the process can be reduced.

This application claims priority to Taiwan Patent Application No. 095139317 filed on Oct. 25, 2006.

### CROSS-REFERENCES TO RELATED APPLICATIONS

Not applicable.

### BACKGROUND OF THE INVENTION

1. Field of the Invention

The subject invention relates to a method of depositing a thin film, and a system and a device for the method; the invention especially relates to a method of providing a thin film by repeated deposition, and a system and a device for the method.

2. Descriptions of the Related Art

As semiconductor devices are miniaturized, the gaps between the semiconductor devices are decreasing, raising the aspect ratio accordingly. The capability of filling the gap is important for avoiding apertures and voids. A prior method of high density plasma chemical vapor deposition (HDP CVD) can no longer meet this gap-filling requirement. Therefore, a CVD method conducted with the use of a mixture of ozone and tetraethylorthosilicate (TEOS) has been developed to provide a silicon-containing oxide layer to fill the gap of a structure with a high aspect ratio as mentioned above.

In general, the silicon-containing oxide layer provided by the O₃-TEOS CVD method is more capable of conformal film deposition and step coverage to meet the miniaturization requirement as mentioned above. However, the method also has its disadvantages. Specifically, an as-deposited thin oxide film formed by that method is loose and has poor quality. The shallow trench structure formed from a thin film with poor quality will reduce the yield of the product. For example, seams between gates in a semiconductor device will result in a short issue between the gates. The divots formed around the edges of the shallow trench isolation will result in leakage, or even the pulling down of the global TEOS that will result in unwanted topography.

In view of the above-mentioned disadvantages, a post anneal process has been proposed to increase the density of the thin film and to improve the quality thereof. For instance, a thermal treatment of the thin film by conducting a steam annealing (a pyrolysis conducted with the use of hydrogen and oxygen) or dry annealing (using nitrogen or oxygen) in a high temperature furnace can improve the density of the film and reduce the etching rate of the subsequent wet etching processes. Although these methods can improve the quality of the thin films, they require a long operation time and a high annealing temperature. As a result, the thermal budget increases substantially.

Therefore, a method for improving the quality of the thin film and an equipment for conducting the method are essential for meeting the requirements during the miniaturizing of semiconductor devices.

### SUMMARY OF THE INVENTION

One objective of the subject invention is to provide a gas delivering system, which comprises a shower head used for providing reaction gases to deposit a thin film; and a thermal treatment system integrated into the shower head, used for heating the thin film to substantially increase the density of the film.

Another objective of the subject invention is to provide a chemical vapor deposition device which comprises a reaction chamber; a shower head used for providing reaction gases to deposit a thin film; and a thermal treatment system integrated into the shower head, used for heating the thin film to substantially increase the density of the film.

A further objective of the subject invention is to provide a method for an in situ deposition of a thin film on a wafer, which comprises the following steps: (a) conducting a chemical vapor deposition to deposit a thin film on a wafer; (b) conducting a rapid thermal process on the thin film; and (c) repeating steps (a) and (b) until the accumulated thickness of the thin film reaches a predetermined thickness, wherein steps (a) and (b) are conducted in the same reaction chamber.

The detailed technology and preferred embodiments implemented for the subject invention are described in the following paragraphs accompanying the appended figures for people skilled in this field to well appreciate the features of the claimed invention.

### BRIEF DESCRIPTION OF THE DRAWINGS

FIG. 1 depicts an exemplary embodiment of the device of the present invention for an in situ thermal treatment of a deposited thin film;

FIG. 2A depicts an upward view of an exemplary embodiment of a shower head in the device of the present invention;

FIG. 2B depicts an enlarged view for one part of FIG. 2A;

FIG. 2C depicts an exemplary embodiment of a cooling system of the device of the present invention; and

FIG. 3 depicts a time chart of temperature and reaction gas variations during the process of the present invention.

### DESCRIPTION OF THE PREFERRED EMBODIMENT

The following disclosure only depicts the present invention that simultaneously conducts an in situ CVD and a related thermal treatment in conventional processes of manufacturing semiconductor devices. Other unrelated processes or components are omitted, such as the susceptor for carrying a wafer in a known deposition chamber, the heater integrated into the susceptor, and the vacuuming device disposed in the chamber.

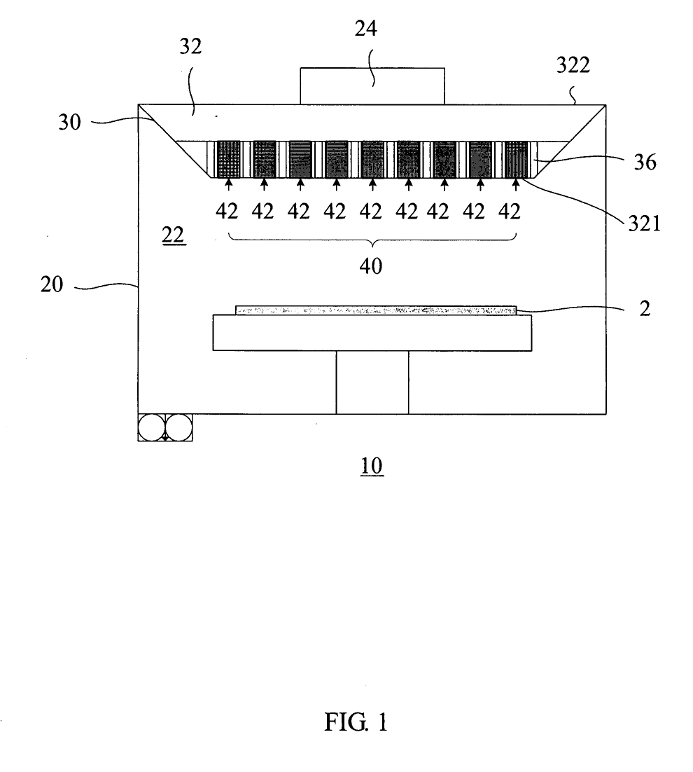

FIG. 1 illustrates an embodiment of the present invention, a CVD device 10, for an in situ thermal treatment of film deposition. As described above, the following disclosure emphasizes only the contents related to the invention.

The CVD device 10 comprises a reaction chamber 20, a gas delivering system 30 and a thermal treatment system 40. The reaction chamber 20 comprises a room 22 defined by a plurality of sidewalls of the reaction chamber. The room 22 provides a space not only for a wafer 2 to be processed (wafer 2 is also shown in the drawings for illustration), but also for other components (as described later) and specific manufacturing processes conducted therein. In addition, the reaction chamber 20 connects to an external gas supplier (e.g., a gas tank containing reaction gases) via a gas inlet 24 for guiding reaction gases into the reaction chamber 20. In one embodiment, the gas inlet 24 can be disposed on the sidewall of the reaction chamber 20 or outside the reaction chamber 20 with proper gas pipes connecting therebetween.

Next, the gas delivering system 30 of the CVD device 10 is disposed inside the room 22 and is used to guide reaction gases into the reaction chamber 20 for depositing a thin film onto the surface of the wafer 2. Moreover, the thermal treatment system 40 is integrated into the gas delivering system 30 for an in situ thermal treatment of an as-deposited thin film to substantially increase the density of the film.

Specifically, (still referring to FIG. 1), the gas delivering system 30 comprises a shower head 32 with a surface 321 that is exposed to the reaction chamber 20, and another surface 322 opposite to the surface 321 that connects to the gas inlet 24 for guiding the reaction gases into the chamber 20 via the surface 321. Moreover, the shower head 32 further comprises a plurality of containing cells 34 and a plurality of channels 36 surrounding each of the containing cells 34. Preferably, the containing cells 34 are uniformly disposed in the shower head 32. In addition, each of the containing cells 34 comprises an opening 341 disposed on the surface 321 and facing the room 22 of the reaction chamber 20. One end of each channel 36 comprises an outlet 361 disposed on the surface 321, while the other end connects to the gas inlet 24 outside the reaction chamber 20 for guiding reaction gases into the reaction chamber 20 via channels 36.

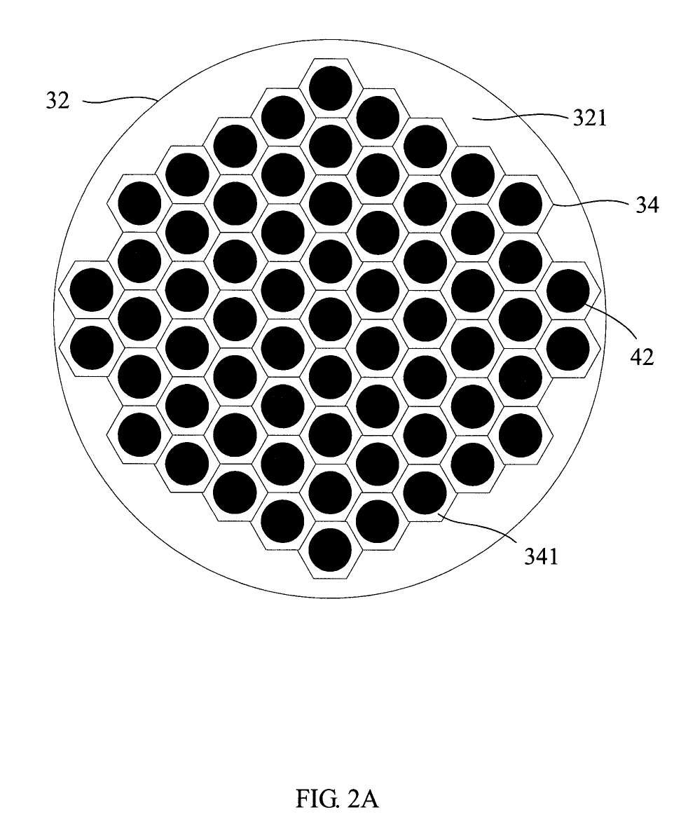

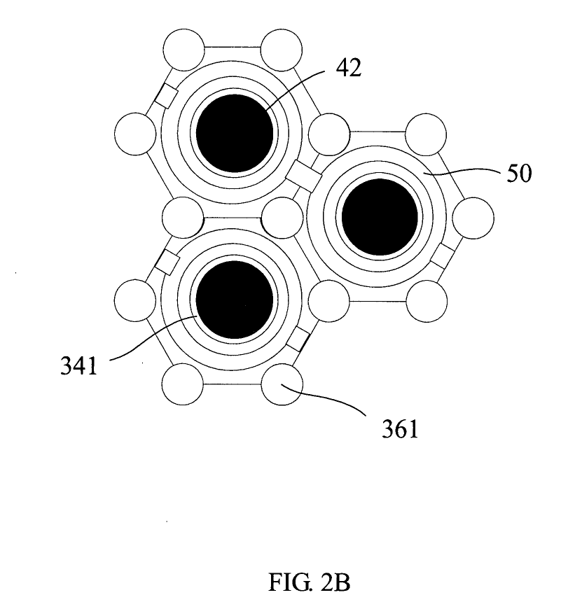

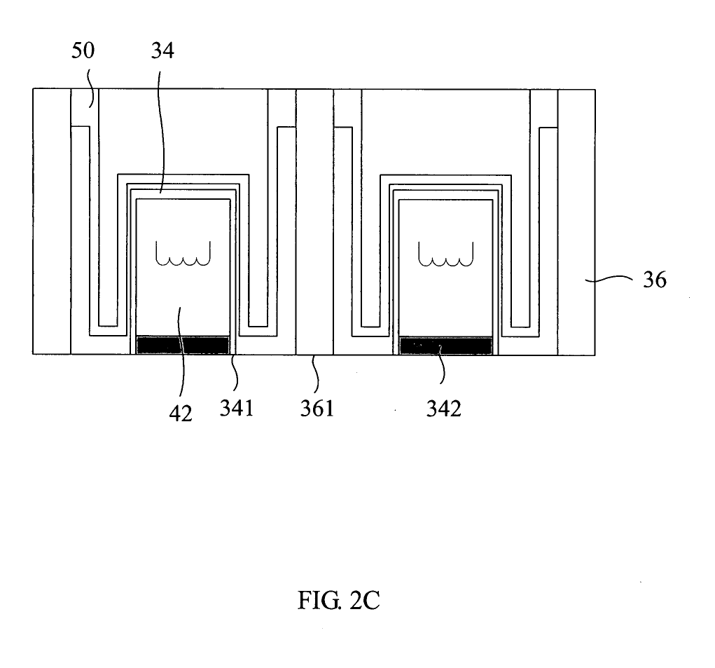

The thermal treatment system 40 comprises a plurality of lamps 42, with each of the lamps 42 is disposed inside each respective containing cell 34 to provide heat energy for conducting a rapid thermal anneal (RTA) on the wafer 2. FIG. 2A illustrates an upward view of one embodiment of the shower head 32, wherein the openings 341 of the containing cells 34 are arranged in a matrix and uniformly disposed on the surface 321 of the shower head 32. That is, the lamps 42 inside the containing cells 34 are also arranged in a matrix inside the shower head 32 for providing a uniform rapid heating source to the wafer 2 inside the reaction chamber 20.

Preferably, the outlets 361 of the channels 36 in the shower head 32 are disposed in a honeycomb matrix on the surface 321 corresponding to the matrix of the lamps 42. Each of the containing cells 34 is surrounded by six channels 36 with a constant distance therebetween, as illustrated in FIG. 2B. It is noted that the matrix formed by the cells 34 and the honeycomb matrix formed by the channels 36 are only examples adopted by the invention; other arrays suitable for providing uniform deposition and thermal treatment in the reaction chamber can be applied to the invention as well.

The CVD device of the invention integrates the gas delivering system used for the CVD process, and the thermal treatment system used for the RTA process into a reaction chamber, so as to conduct an in situ thermal treatment for thin film deposition. Preferably, the CVD device further comprises a cooling subsystem for precisely controlling the temperature for the deposition and thermal treatment.

FIG. 2B and FIG. 2C illustrate an embodiment of the CVD device 40 in which the gas delivering system 30 further comprises a cooling subsystem 50. The cooling subsystem 50 is surrounding the containing cells 34 and the channels 36 for precise temperature control. For example, the cooling subsystem 50 comprises a plurality of coolant-containing pipes that are disposed in the shower head 32 and surrounds the containing cells 34 and the channels 36 to maintain the containing cells 34 and the channels 36 at temperature(s) less than that of the lamps 42 inside the containing cells 34. The coolant can be such as, but not limited to, water. Thus, the cooling subsytem 50 can prevent undesired reactions of gases inside the channels 36 and/or near the outlets 361 due to a high temperature surrounding the lamps 42.

In addition, it is preferred that isolating plates 342 are disposed on the openings 341 of the containing cells 34. The isolating plates 342 protect the lamps 42 inside the containing cells 34 and keep them from damage, such as corrosion by plasma cleaning of reaction chamber 20. Each of the isolating plate 342 can be independently made of ruby, sapphire, or quartz.

The following will describe in detail the application of the above-mentioned devices to the manufacture of a semiconductor device to provide a thin film with high density and good step coverage. Compared with the prior art, which required two different equipments for conducting CVD deposition and related thermal treatment, one advantage of the CVD device of the invention is that those two processes are conducted in the same reaction chamber. Therefore, a thin film can be deposited on a wafer using the CVD device. The method of depositing a thin film on a wafer in accordance with the present invention utilizes the device that is capable of conducting an in situ thermal treatment for thin film deposition, and alternately conducts a thin film deposition and an annealing process to provide a deposited film with good quality. As a result, pores are not generated due to the significant amount of shrinkage that happens in the operation of forming a bulk oxide layer in one deposition and then annealing the layer.

First in the manufacturing process, a cycle with a step for thin film deposition and a step for thermal treatment is conducted with a constant time span for easy operation. A predetermined thickness of the thin film on the wafer is verified first, and then, equalized to obtain a film sub-thickness of one cycle according to the desired cycle numbers. The cycle can also be conducted with a different time span to accumulate layers with different thicknesses. Using the cycles of deposition and thermal treatment achieves the desired film thickness, increasing the density and quality of the film.

Next, the reaction gases for thin film deposition are guided into the reaction chamber to deposit a thin film with a certain sub-thickness using a CVD process such as atomic layer deposition. The sub-thickness can range from such as, but not limited to, 50 Å to 500 Å.

Next, an RTA process is conducted to heat the thin film and increase its density. In the aforementioned embodiment that the sub-thickness of the thin film is from 50 Å to 500 Å, the time needed for thermal treatment is less than 5 minutes and can be about 1 minute. In addition, thermal treatment is conducted at a temperature ranging form 300° C. to 1500° C., and preferably, from 400° C. to 1000° C. It is noted that a relative low temperature should be maintained inside the channels and near the outlets in the shower head to keep undesired gas phase reactions from happening in those areas. If necessary, the above-mentioned cooling subsystem in the shower head can be used to decrease the temperature.

A thin film deposition and a thermal treatment are alternately conducted until the accumulated thickness of the film on the wafer reaches the predetermined thickness.

For example, for filling a silicon oxide layer into a shallow trench with a width of 2000 Å on a wafer, reaction gases, including ozone and TEOS, are guided into the reaction chamber. Because the oxide layer formed from the reaction-deposition of ozone and TEOS, is capable of step coverage, the oxide layer can cover the entire shallow trench by filling the shallow trench from its two sides simultaneously, as the accumulated thickness of the oxide layer approaching about 1000 Å. On the other hand, if three to six process cycles are needed to complete the whole process, the thickness of the oxide layer formed during each cycle is between 100 Å to 400 Å.

Next, after thin film deposition is conducted, thermal treatment is sequentially conducted. Preferably, the supply of reaction gases is ceased and other gas is introduced into the reaction chamber in advance, to provide a proper environment for thermal treatment. The environmental gas can be, but not limited to, a gas selected from a group consisting of nitrogen, oxygen, argon, nitrous oxide, helium, hydrogen and a combination thereof. The environmental gas is used to provide a cooling effect during the thin film deposition process to reduce the temperature near the heating lamp, the shower head, and the wafer surface in the reaction chamber.

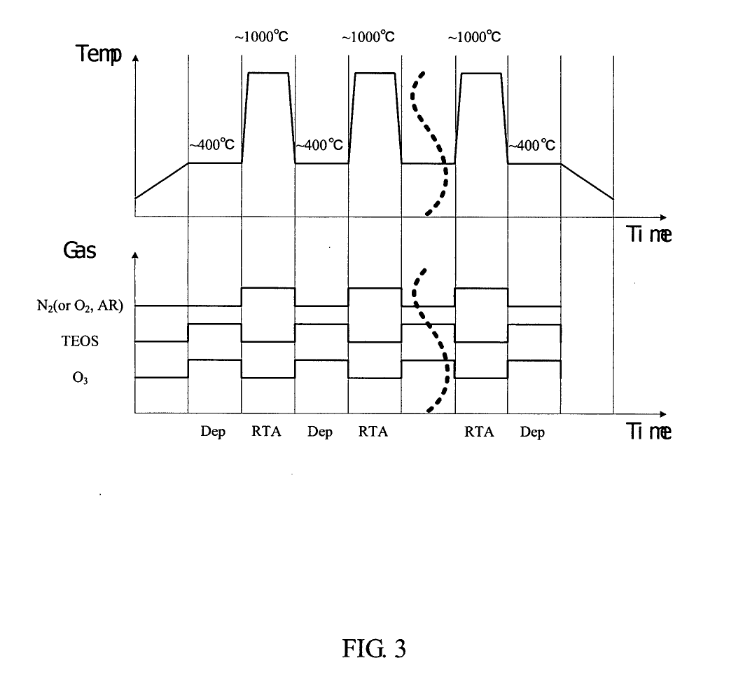

The above-mentioned processes of thin film deposition and thermal treatment are repeated alternatively until the predetermined thickness of the film on the wafer is obtained. FIG. 3 illustrates a time chart with the temperature and reaction gas variations during thin film deposition and thermal treatment.

In summary, the prior art uses independent equipments for conducting thin film deposition and thermal treatment. Therefore, in view of practical applications, the conventional method should complete the thin film deposition in a single process, while conducting thermal treatment in another process. It is impossible to ship a wafer between different equipments for conducting multi-steps of deposition and thermal treatment. On the contrary, the CVD reaction device of the invention can be used to easily conduct deposition and thermal treatment in one reaction chamber to provide a thin film with good quality, good step coverage and gap-filling, and effectively enhances the density thereof.

In addition, the CVD reaction device of the invention can keep the wafer from contamination or mechanical damages that are possibly generated during the shipping of the wafer between different equipments in the prior art. The time for shipping will be saved as well. Moreover, it is found that the method of an in situ thermal treatment for thin film deposition of the invention can decrease the time for annealing and reduce the thermal budget of the whole process accordingly. Therefore, a sufficient thermal budget can be provided for the sequential processes.

The above examples are only intended to illustrate the principle and efficacy of the subject invention, not to limit the subject invention. Any people skilled in this field may proceed with modifications and changes to the above examples without departing from the technical principle and spirit of the subject invention. Therefore, the scope of protection of the subject invention is covered in the following claims as appended.

What is claimed is:

1. A gas delivering system, comprising:
a shower head for providing reaction gases that will react and deposit a thin film; and
a thermal treatment system, integrated into the shower head for heating the thin film to increase its density substantially.

2. The gas delivering system of claim 1, wherein the thermal treatment system comprises a plurality of lamps for providing heat energy.

3. The gas delivering system of claim 2, wherein the shower head comprises a surface and a plurality of containing cells, each of the containing cells contains a lamp and an opening disposed on the surface.

4. The gas delivering system of claim 3, wherein the shower head further comprises a plurality of channels for delivering the reaction gases, while each of the channels has an outlet on the surface.

5. The gas delivering system of claim 4, wherein the shower head further comprises a cooling subsystem for maintaining the channels at a low temperature.

6. The gas delivering system of claim 4, wherein the containing cells are disposed uniformly in the shower head.

7. The gas delivering system of claim 6, wherein the outlets on the surface are disposed in a honeycomb matrix that each of the containing cells are surrounded by a plurality of the channels.

8. The gas delivering system of claim 3, wherein the shower head further comprises a plurality of isolating plates, disposed on the openings of the containing cells and covering the openings.

9. The gas delivering system of claim 8, wherein each of the isolating plates is independently made of ruby, sapphire or quartz.

10. A chemical vapor deposition reaction device, comprising:
a reaction chamber; and
a gas delivering system of claim 1.

11. A method for providing a film on a wafer by repeated deposition, comprising:
(a) conducting a chemical vapor deposition to deposit a thin film on a wafer;
(b) conducting a rapid thermal annealing process to the thin film; and
(c) repeating the steps (a) and (b) until the accumulated thickness of the film reaches a predetermined thickness,
wherein the steps (a) and (b) are conducted in the same reaction chamber.

12. The method of claim 11, wherein the chemical vapor deposition is conducted with the use of ozone and TEOS.

13. The method of claim 12, wherein the thin film comprises a silicon-containing oxide layer.

14. The method of claim 11, wherein the thickness of the thin film formed in the step (a) ranges from 50 Å to 500 Å.

15. The method of claim 11, wherein the step (b) is conducted for less than 5 minutes.

16. The method of claim 11, wherein the step (b) is conducted at a temperature ranging from 400° C. to 1500° C.

17. The method of claim 16, wherein the step (b) is conducted at an atmosphere comprising a gas selected from a group consisting of nitrogen, oxygen, argon, nitrous oxide, helium, hydrogen and a combination thereof.

18. The method of claim 11, wherein the method is conducted in the reaction device of claim 10.
